(19) United States
(12) Patent Application Publication
(10) Pub. No.: US 2026/0257492 A1
(43) Pub. Date: Sep. 3, 2026

(54) THERMAL PRINT HEAD AND METHOD OF MANUFACTURING THE SAME

(71) Applicant: ROHM CO., LTD., Kyoto-shi (JP)

(72) Inventor: Sota NAKAJIMA, Kyoto-shi (JP)

(21) Appl. No.: 19/545,795

(22) Filed: Feb. 20, 2026

(30) Foreign Application Priority Data
Feb. 28, 2025 (JP) 2025-031361

(51) Int. Cl. B41J 2/335; B41J 2/34; B41J 2/35; B41J 2/375; H05K 3/36

(52) U.S. Cl. CPC B41J 2/3359; B41J 2/33515; B41J 2/3352; B41J 2/3353; B41J 2/33535; B41J 2/3355; B41J 2/33575; B41J 2/3358; B41J 2/34; B41J 2/35; B41J 2/375; H05K 3/361

(57) ABSTRACT

A thermal print head has a heating element substrate and a wiring substrate. The heating element substrate includes: a semiconductor substrate having a first main surface; a plurality of heating portions arranged on the first main surface; and a first wiring layer arranged on the first main surface and constituting an energizing path to the plurality of heating portions. The wiring substrate includes: a ceramic substrate having a second main surface; and a second wiring layer arranged on the second main surface and electrically connected to the first wiring layer. The third main surface of the semiconductor substrate facing opposite to the first main surface is bonded to the upper surface of the wiring substrate where the second wiring layer is formed. As seen from the normal direction of the second main surface, the entire heating element substrate overlaps with the second wiring layer.

### CROSS REFERENCE TO RELATED APPLICATIONS AND INCORPORATION BY REFERENCE

The present application is based on, and claims priority from Japanese Patent Application No. 2025-031361, filed on February 28, 2025, the entire contents of which are incorporated herein by reference.

### TECHNICAL FIELD

The present disclosure relates to a thermal print head and method of manufacturing the same.

### BACKGROUND ART

In order to realize high-quality printing, a thermal print head has been known in which a heating substrate supporting a plurality of heating portions for locally heating a print medium is made of a single crystal semiconductor such as silicon (Si). A printed circuit board (PCB) was connected to the heating substrate made of Si, and a flexible printed circuit board was connected to the PCB.

### SUMMARY

The manufacturing method of a PCB includes a photolithography process and a process of punching the substrate with a die. These complicated manufacturing processes increase the manufacturing cost of the PCB.

An object of the present disclosure is to provide a thermal print head and a method of manufacturing the same, which can reduce the manufacturing cost while maintaining high-quality printing performance.

In order to solve the above problems, a thermal print head according to one aspect of the present disclosure is provided with a heating element substrate and a wiring substrate. The heating element substrate includes: a semiconductor substrate having a first main surface; a plurality of heating portions arranged on the first main surface in a main scanning direction; and a first wiring layer arranged on the first main surface and constituting an energizing path to the plurality of heating portions. The wiring substrate includes: a ceramic substrate having a second main surface; and a second wiring layer arranged on the second main surface. The second wiring layer is electrically connected to the first wiring layer. The third main surface of the semiconductor substrate facing opposite to the first main surface is bonded to the upper surface of the wiring substrate where the second wiring layer is formed. As seen from the normal direction of the second main surface, the entire heating element substrate overlaps with the second wiring layer.

### BRIEF DESCRIPTION OF DRAWINGS

FIG. 1A is a perspective view illustrating an entire thermal print head according to an embodiment.

FIG. 1B is an enlarged perspective view of a region G1B in FIG. 1A.

FIG. 1C is an enlarged perspective view of a region G1C in FIG. 1A.

FIG. 2A is a plan view illustrating an entire wiring substrate provided in the thermal print head according to the embodiment.

FIG. 2B is a plan view in which a heating element substrate, a plurality of drive ICs (integrated circuits), and a third protective film are added to the entire wiring substrate in FIG. 2A.

FIG. 3A is a cross-sectional view of the thermal print head according to the embodiment taken along IIIA-IIIA in FIG. 2B.

FIG. 3B is an enlarged cross-sectional view of a region G3B in FIG. 3A.

FIG. 3C is an enlarged cross-sectional view of a region G3C in FIG. 3A.

FIG. 4A is a cross-sectional view of the thermal print head according to the embodiment taken along IVA-IVA in FIG. 2B.

FIG. 4B is an enlarged cross-sectional view of a region G4B in FIG. 4A.

FIG. 4C is an enlarged cross-sectional view of a wire in FIG. 4A.

FIG. 5 is an enlarged plan view of a region G5 in FIG. 2B.

FIG. 6 is a plan view illustrating the main portion of the heating element substrate provided in the thermal print head according to the embodiment.

### DETAILED DESCRIPTION

Hereinafter, a thermal print head according to an embodiment will be described in detail with reference to the drawings. However, it should be noted that the drawings are schematic, and the relationship between the thickness and the plane dimension, the ratio of the thickness of each component, and the like may differ from the actual one. In addition, it is needless to say that the drawings may include components in which the dimensional relationships or ratios differ among the drawings.

Note that the embodiment described below represents a comprehensive or specific example. Numerical values, shapes, materials, components, and installation positions and connection forms of the components illustrated in the following embodiment are merely examples, and are not intended to limit the present disclosure. In addition, among the components in the following embodiment, components that are not described in the independent claim(s), which represents the highest concept, will be described as optional components. Moreover, the dimensional ratios of the drawings are exaggerated for the convenience of description, and may be different from actual ratios in some cases. Furthermore, similar components may be included in the following embodiment and modified examples thereof, and common reference numerals are given to similar components, and redundant descriptions are omitted.

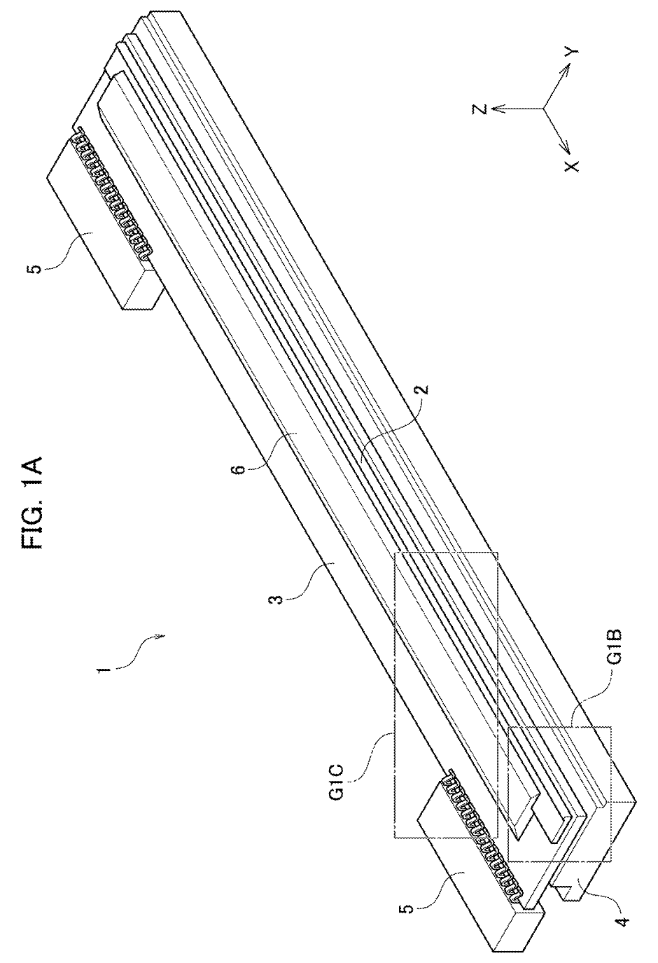

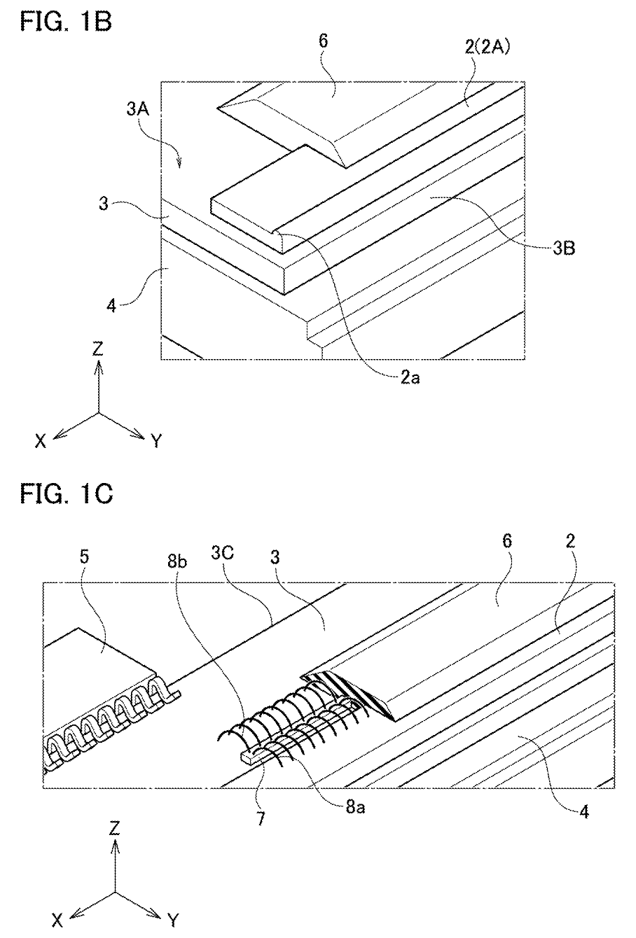

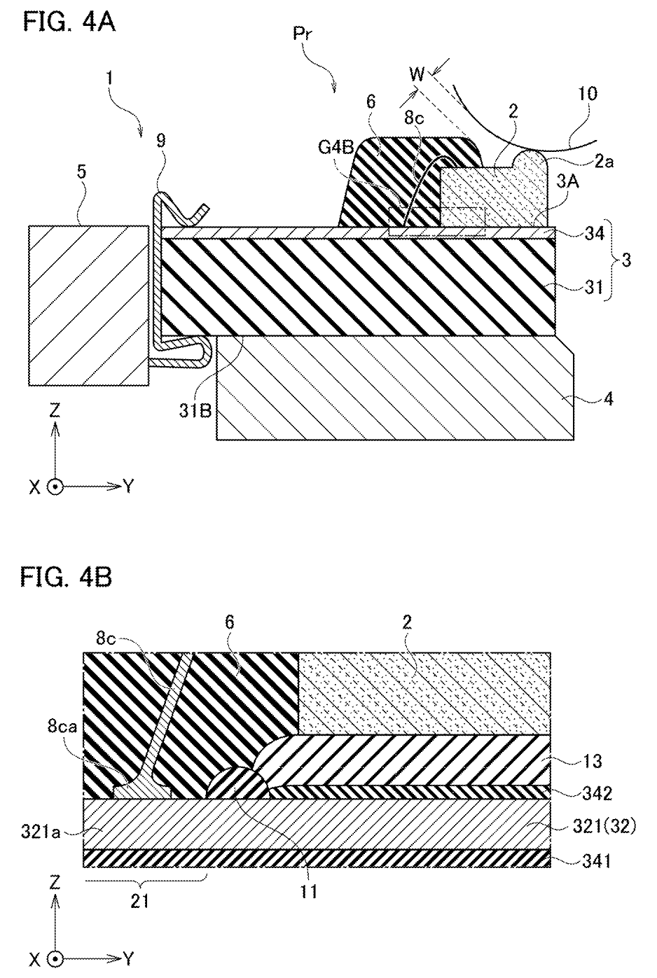

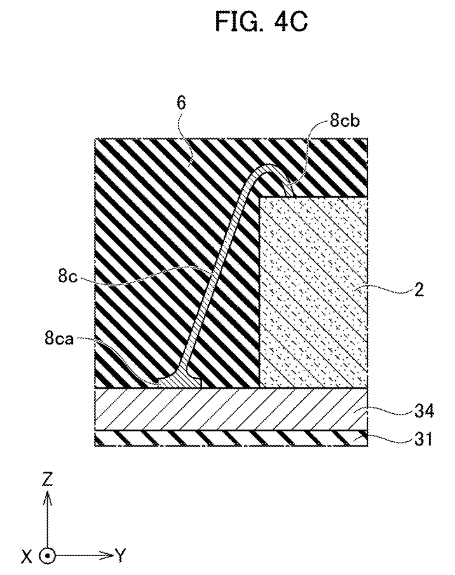

FIGS. 1A to 6 illustrate a thermal print head 1 according to an embodiment. As illustrated in FIGS. 1A to 1C, the thermal print head 1 includes a heating element substrate 2, a wiring substrate 3, a plurality of drive ICs 7, a second protective film 6, a connector 5, and a heat sink 4. The thermal print head 1 is incorporated in a thermal printer Pr which performs printing on a print medium (not illustrated) sandwiched between the thermal print head 1 and a platen roller 10 (see FIG. 4A). The thermal printer Pr includes the thermal print head 1 and the platen roller 10. The platen roller 10 is positioned directly opposite to the thermal print head 1. The print medium is sandwiched between the thermal print head 1 and the platen roller 10 and conveyed in the sub-scanning direction (Y direction) by the platen roller 10. Examples of such a print medium include thermal paper for preparing a bar code sheet and a date code sheet. The thermal print head 1 includes a plurality of heating portions according to a configuration to be described later in detail, and printing is performed on the print medium by selectively driving the plurality of heating portions.

The overall configuration of the thermal print head 1 according to a first embodiment will be described with reference to FIGS. 1A to 1C. The heating element substrate 2 is bonded to the upper surface 3A of the wiring substrate 3 by an adhesive (not illustrated). Both the heating element substrate 2 and the wiring substrate 3 have an elongated shape extending in the main scanning direction of the thermal print head 1.

In the following description, the XYZ coordinate system as an example of the Cartesian coordinate system will be used. A plane parallel to the upper surface 3A of the wiring substrate 3 is defined as an XY plane, and a direction perpendicular to the XY plane is defined as the Z direction. In the XY plane, the main scanning direction of the thermal print head 1 is defined as the X direction, and a direction perpendicular to the main scanning direction, that is, the sub-scanning direction is defined as the Y direction. The surface facing the positive side of the Z direction is called an upper surface, and the surface facing the negative side of the Z direction is called a lower surface.

The lower surface of the heating element substrate 2 is bonded to the upper surface 3A of the wiring substrate 3. A convex portion 2a extending in the main scanning direction is formed on the upper surface 2A of the heating element substrate 2. A plurality of heating portions (not illustrated) for locally heating a print medium to be printed by the thermal print head 1 are arranged on the convex portion 2a. As illustrated in FIGS. 1A to 1C, the entire heating element substrate 2 is arranged on the upper surface 3A of the wiring substrate 3.

A drive IC 7 is arranged adjacent to the heating element substrate 2 on the upper surface 3A of the wiring substrate 3. The drive IC 7 is electrically connected to a first wiring layer (not illustrated) formed on the upper surface 2A of the heating element substrate 2 by a plurality of wires 8a and a plurality of wires 8b. The drive IC 7 is electrically connected to a second wiring layer (not illustrated) formed on the upper surface 3A of the wiring substrate 3 by a plurality of wires 8b. The drive IC 7 transmits a driving signal to the heating element substrate 2, and selectively drives a plurality of heating portions by individually passing a current to the plurality of heating portions. A plurality of drive ICs 7 are provided according to the number of heating portions. The drive IC 7 and the plurality of wires 8a and 8b are covered with the second protective film 6. The second protective film 6 is made of, for example, an insulating resin and is, for example, black. The second protective film 6 is formed so as to straddle the heating element substrate 2 and the wiring substrate 3, and extends in the main scanning direction. Note that in FIG. 1C, a part of the second protective film 6 is removed to illustrate the drive IC 7 and the plurality of wires 8a and 8b. A conductor such as gold can be used as the wire 8a and wire 8b. The same applies to the wire 8c, which will be described later.

The heating element substrate 2 is arranged at the first end 3B of the wiring substrate 3 on the downstream side (positive side) in the sub-scanning direction (Y direction). The connector 5 is attached to the second end 3C of the wiring substrate 3 on the upstream side in the sub-scanning direction that is the opposite direction to the first end 3B. The connector 5 is provided for electrical connection between the thermal print head 1 and external devices such as the thermal printer Pr (not illustrated). The connector 5 is fixed to and electrically connected to the wiring substrate 3 via a metal clip 9.

The heat sink 4 is bonded to the lower surface of the wiring substrate 3 facing the opposite direction to the upper surface 3A. Heat generated in the heating element substrate 2 is transmitted to the heat sink 4 via the wiring substrate 3. As a constituent material of the heat sink 4, for example, aluminum or copper can be used.

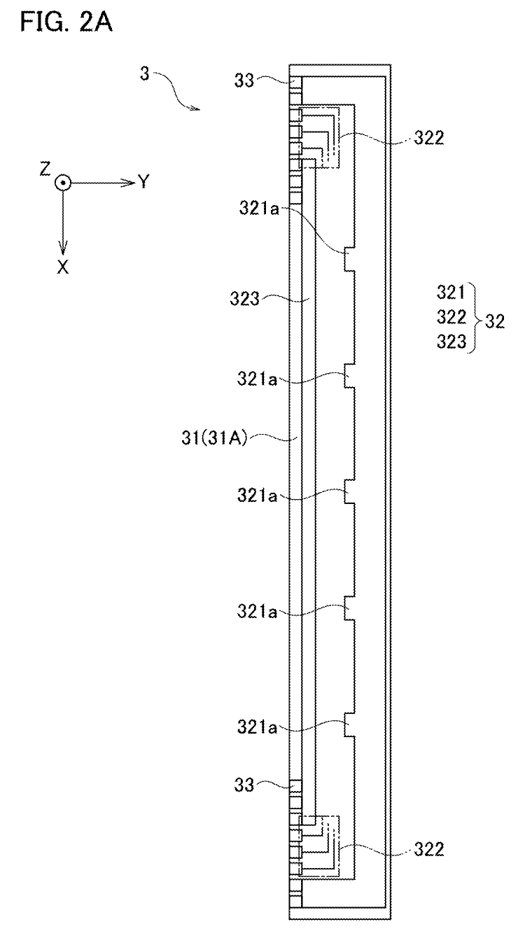

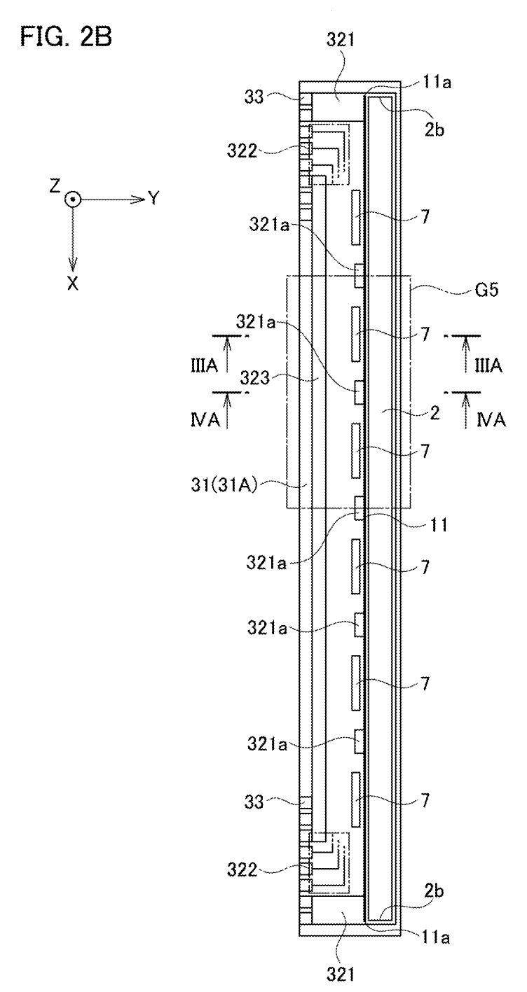

FIG. 2A is a plan view illustrating the entire wiring substrate 3 provided in the thermal print head 1 according to the embodiment. The wiring substrate 3 includes a ceramic substrate 31, a second wiring layer 32 arranged on the upper surface (second main surface 31A) of the ceramic substrate 31, and electrode pads 33. The second wiring layer 32 includes a common wiring 321, an individual wiring 322, and a ground wiring 323. The common wiring 321, the individual wiring 322, and the ground wiring 323 are electrically connected to the connector 5 (see FIGS. 1A to 1C) via the electrode pads 33. The common wiring 321 and the ground wiring 323 are wiring with relatively wide line widths extending in the main scanning direction (X direction), and are arranged in the sub-scanning direction (Y direction) at regular intervals. Meanwhile, the individual wiring 322 includes a plurality of wirings with relatively narrow line widths, and extends in the main scanning direction between the common wiring 321 and the ground wiring 323, although not illustrated. The common wiring 321 is referred to as common wiring. The common wiring 321 includes a plurality of protrusions 321a protruding upstream in the sub-scanning direction, that is, on the negative side in the Y direction. The plurality of protrusions 321a are arranged in the X direction at regular intervals. As a constituent material of the ceramic substrate 31, alumina having high thermal conductivity can be used. Examples of constituent materials of the second wiring layer 32 include gold, aluminum, silver, and copper.

FIG. 2B is a plan view in which the heating element substrate 2, the plurality of drive ICs 7, and the third protective film 11 are added to the entire wiring substrate 3 in FIG. 2A. The heating element substrate 2 is arranged on the common wiring 321. FIG. 2B is a view as seen from the normal direction (Z direction) of the second main surface 31A of the ceramic substrate 31. As seen from the normal direction of the second main surface 31A of the ceramic substrate 31, the entire heating element substrate 2 overlaps with the common wiring 321. In other words, the outer edge of the heating element substrate 2 is positioned inward of the outer edge of the common wiring 321. As seen from the normal direction of the second main surface 31A of the ceramic substrate 31, the plurality of protrusions 321a of the common wiring 321 do not overlap with the heating element substrate 2.

The plurality of drive ICs 7 are arranged on the second main surface 31A of the ceramic substrate 31 so as to sandwich each of the protrusions 321a from the X direction. The plurality of drive ICs 7 are arranged along the heating element substrate 2 in the main scanning direction.

On the second main surface 31A of the ceramic substrate 31, the third protective film 11 is arranged between the plurality of protrusions 321a and the heating element substrate 2. The third protective film 11 extends in the main scanning direction. The end portion 11a of the third protective film 11 in the main scanning direction is at the same position in the main scanning direction as the end portion 2b of the heating element substrate 2, or the end portion 11a of the third protective film 11 in the main scanning direction is positioned outward of the end portion 2b of the heating element substrate 2 in the main scanning direction.

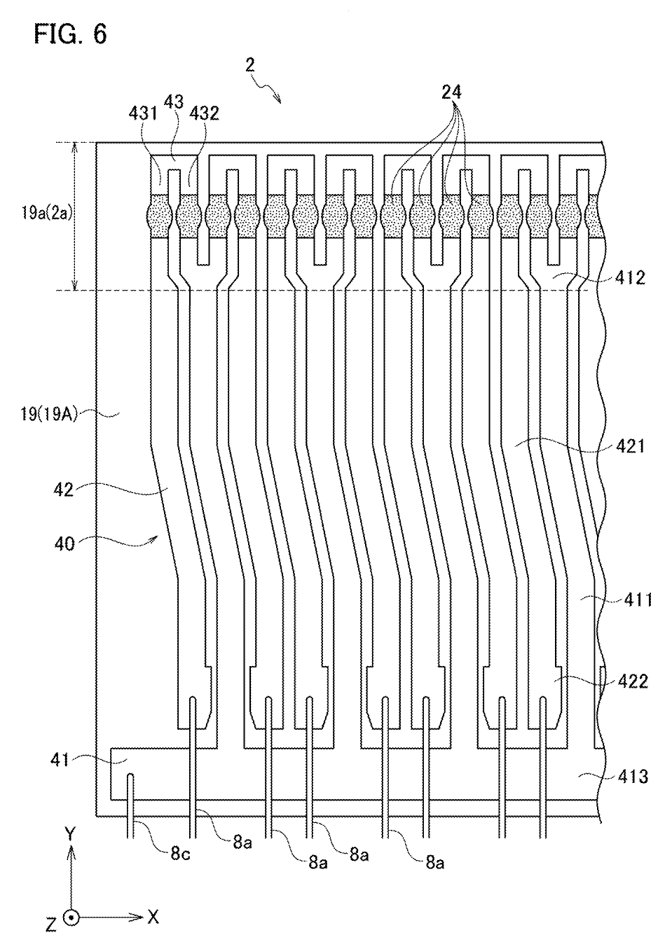

FIG. 6 is a plan view illustrating the main portion of the heating element substrate 2 provided in the thermal print head 1 according to the embodiment. The heating element substrate 2 includes a semiconductor substrate 19 made of, for example, a single crystal semiconductor such as silicon, a plurality of heating portions 24 arranged in the main scanning direction (X direction) on the upper surface (first main surface 19A) of the semiconductor substrate 19, and a first wiring layer 40 arranged on the first main surface 19A and constituting an energizing path to the plurality of heating portions 24. Examples of the constituent materials of the first wiring layer 40 include copper (Cu), aluminum (Al), and titanium (Ti). The method of forming the first wiring layer 40 is not particularly limited, but can be formed by, for example, a film forming process such as a sputtering method or a chemical vapor deposition method (CVD method), or a patterning process by photolithography. The plurality of heating portions 24 are made of a material having a resistance value per unit length in the sub-scanning direction (Y direction) higher than that of the first wiring layer 40. Examples of the constituent material of the plurality of heating portions 24 include tantalum nitride (TaN).

A convex portion 19a corresponding to the convex portion 2a of the heating element substrate 2 illustrated in FIGS. 1A to 1B is formed on the downstream side of the first main surface 19A of the semiconductor substrate 19 in the sub-scanning direction, that is, at the end portion on the positive side in the Y direction. The convex portion 19a extends in the main scanning direction (X direction). At the center of the convex portion 19a in the Y direction, the plurality of heating portions 24 are arranged in the X direction at predetermined intervals. The plurality of heating portions 24 are supported by the semiconductor substrate 19.

The first wiring layer 40 constitutes an energizing path for energizing the plurality of heating portions 24. The first wiring layer 40 is supported by the semiconductor substrate 19. The thickness of the first wiring layer 40 is not particularly limited, but is, for example, 0.3 μm to 2.0 μm. The first wiring layer 40 includes a common electrode 41, a plurality of individual electrodes 42, and a plurality of relay electrodes 43.

Each of the individual electrodes 42 has a strip-like portion 421 extending generally in the Y direction. The plurality of individual electrodes 42 are arranged on the upstream side (negative side) in the Y direction with respect to the plurality of heating portions 24. Each of the individual electrodes 42 is electrically connected to a different heating portion 24. The downstream-side (positive side) end portions of the plurality of strip-like portions 421 in the Y direction are electrically connected to the upstream-side end portions of the heating portions 24 in the Y direction. The plurality of individual electrodes 42 have the individual pads 422 connected to the upstream side (negative side in the Y direction) end portions of the respective strip-like portions 421 in the Y direction. The individual pads 422 are connected to the wires 8a for electrical connection with the drive ICs 7.

The common electrode 41 has a plurality of strip-like portions 411, a plurality of branch portions 412, and a connecting portion 413, and is arranged on the upstream side in the Y direction with respect to the plurality of heating portions 24. Each of the strip-like portions 411 extends generally in the Y direction. The downstream-side end portion of each of the strip-like portions 411 in the Y direction is connected to the branch portion 412. The branch portion 412 branches into two parts toward the downstream side in the Y direction, and the downstream-side end portions of the two branched parts are electrically connected to the upstream-side end portions of two adjacent heating portions 24 in the Y direction. Each upstream-side end portion of the plurality of strip-like portions 411 in the Y direction is connected to the connecting portion 413. The connecting portion 413 extends in the X direction and is connected to the wire 8c.

The plurality of relay electrodes 43 are arranged on the downstream side in the Y direction with respect to the plurality of heating portions 24. The plurality of relay electrodes 43 have a C-shape opening toward the upstream side in the Y direction and are arranged in the main scanning direction (X direction) at equal intervals. Both end portions 431 and 432 of the relay electrodes 43 are electrically connected to the downstream-side end portions of two adjacent heating portions 24 in the Y direction.

Each of the strip-like portions 411 of the common electrode 41 is arranged to be sandwiched between the strip-like portions 421 of two individual electrodes 42. One strip-like portion 411 and two strip-like portions 421 are alternately arranged in the X direction. Each of the strip-like portions 411 is connected to two adjacent heating portions 24 via the branch portion 412. One of the two heating portions 24 is connected to one of the two individual electrodes 42 via a corresponding relay electrode 43, and the other of the two heating portions 24 is connected to the other of the two individual electrodes 42 via a corresponding relay electrode 43. With such a configuration, when one individual electrode 42 is energized, two adjacent heating portions 24, that is, the heating portion 24 directly connected to the individual electrode 42 and the heating portion 24 indirectly connected thereto via the relay electrode 43, simultaneously generate heat.

The plurality of heating portions 24 and the first wiring layer 40 are covered with a protective layer (not illustrated) except for a pad portion to which the wires 8a and 8c are connected. The protective layer is made of an insulating material and protects the first wiring layer 40 and the plurality of heating portions 24. The material of the protective layer is, for example, SiO2, SiN, SiC, AlN, or the like. The protective layer is composed of a single layer or a plurality of layers of these materials. The thickness of the protective layer is not particularly limited, but is, for example, about 1.0 μm to 10 μm.

In the embodiment, the arrangement and shape of the first wiring layer 40 are not particularly limited. For example, the relay electrode 43 may not be provided, the common electrode 41 may be arranged downstream of the heating portion 24 in the Y direction, and each of the heating portions 24 may be connected to a different common electrode 41 and a different individual electrode 42.

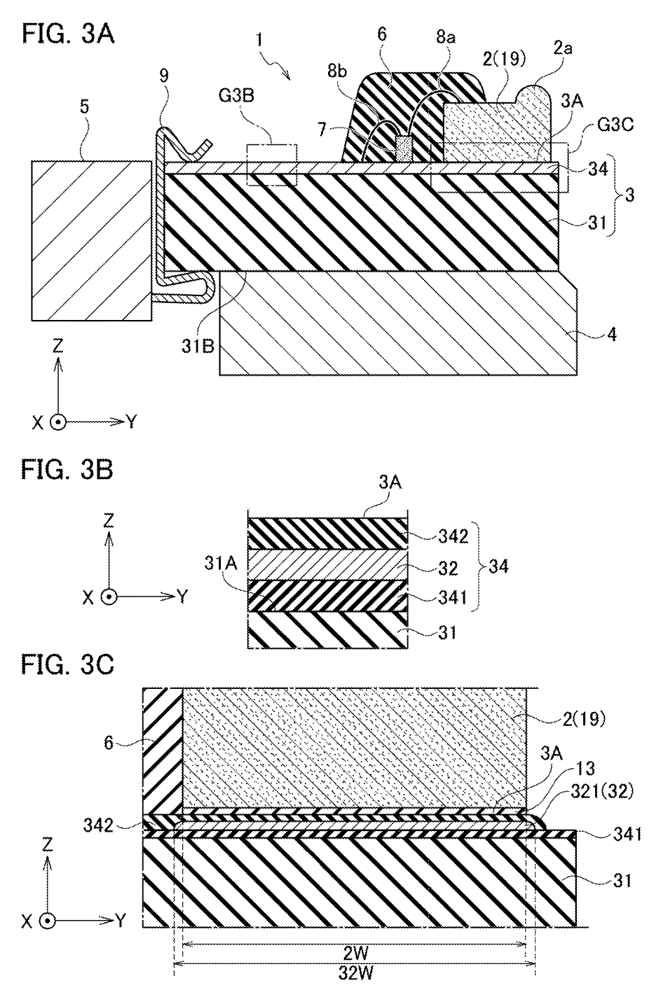

FIG. 3A is a cross-sectional view of the thermal print head 1 according to the embodiment taken along IIIA-IIIA in FIG. 2B. The convex portion 2a is formed on the upper surface of the heating element substrate 2. The convex portion 2a is arranged at the end portion of the heating element substrate 2 on the downstream side in the Y direction (the positive side in the Y direction). A plurality of heating portions 24 illustrated in FIG. 6 are arranged on the convex portion 2a along the X direction that is the main scanning direction.

The lower surface (third main surface) of the semiconductor substrate 19 facing opposite to the upper surface (first main surface) of the semiconductor substrate 19 provided in the heating element substrate 2, is bonded to the upper surface of the wiring substrate 3. The wiring substrate 3 has the ceramic substrate 31 and a laminated structure 34 arranged on the upper surface (second main surface 31A) of the ceramic substrate 31. As illustrated in FIG. 3B, the laminated structure 34 includes a glaze layer 341, the second wiring layer 32, and a first protective film 342. On the second main surface 31A of the ceramic substrate 31, the glaze layer 341, the second wiring layer 32, and the first protective film 342 are laminated in this order. The glaze layer 341 is also referred to as a heat storage layer.

An example of a method of manufacturing the wiring substrate 3 will be described. Glass paste is applied to the second main surface 31A of the ceramic substrate 31 by screen printing. Thereafter, the glaze layer 341 is formed by baking. A conductor paste containing gold or the like is screen-printed on the glaze layer 341 and baked to form the second wiring layer 32 with a required pattern. Glass paste is applied on the second wiring layer 32 and on the glaze layer 341 where the second wiring layer 32 is not formed, and is then baked to form the first protective film 342. Overcoat glass can be used as a constituent material of the first protective film 342.

In the embodiment, of the main surfaces of the ceramic substrate 31, the second wiring layer 32 is printed only on the second main surface 31A However, the second wiring layer 32 may be printed not only on the second main surface 31A of the ceramic substrate 31, but also on the other main surfaces. The surface of the second wiring layer 32 is covered with the first protective film 342 made of an insulating film.

The drive IC 7 is arranged on the upper surface 3A of the wiring substrate 3. The drive IC 7 is arranged adjacent to the heating element substrate 2 and on the upstream side (negative side) of the heating element substrate 2 in the Y direction. The drive IC 7 is electrically connected to the heating element substrate 2 by the wire 8a. More specifically, the drive IC 7 is electrically connected to the individual pad 422 (see FIG. 6) of the plurality of individual electrodes 42 by a plurality of wires 8a. The drive IC 7 can cause a plurality of heating portions 24 to generate heat individually by individually energizing the plurality of individual electrodes 42. The drive IC 7 is electrically connected to the wiring substrate 3 by the wire 8b. More specifically, the drive IC 7 is electrically connected to the second wiring layer 32 on the ceramic substrate 31 by the wire 8b. The drive IC 7 and the wires 8a and 8b are covered with the second protective film 6.

The heat sink 4 is thermally connected to the lower surface (fourth main surface 31B) of the ceramic substrate 31 facing in the opposite direction to the second main surface 31A of the ceramic substrate 31. Specifically, the ceramic substrate 31 and the heat sink 4 are bonded using a thermally conductive adhesive. As the thermally conductive adhesive, for example, a silicone adhesive, a polyimide adhesive, and an epoxy adhesive can be used. As the material of the heat sink 4, for example, aluminum (Al), copper (Cu), and graphite (artificial graphite) can be used.

The connector 5 is electrically and mechanically connected to the end portion of the wiring substrate 3 on the upstream side (negative side) in the Y direction by the metallic clip 9. The clip 9 clamps the wiring substrate 3 between the upper surface 3A and the lower surface (the fourth main surface 31B of the ceramic substrate 31), and is fixed to the wiring substrate 3 by pressing. Although not illustrated, the clip 9 and the second wiring layer 32 are electrically connected at a contact point between the upper surface 3A of the wiring substrate 3 and the clip 9.

FIG. 3C is an enlarged cross-sectional view of the region G3C in FIG. 3A. As illustrated in FIG. 3C, the lower surface (third main surface) of the semiconductor substrate 19 is bonded to the upper surface of the wiring substrate 3 via an adhesive 13 (not illustrated). As the adhesive 13, an adhesive having high thermal conductivity can be used, and for example, a silicone adhesive, a polyimide adhesive, and an epoxy adhesive can be used.

The common wiring 321 of the second wiring layer 32 is arranged between the heating element substrate 2 and the ceramic substrate 31. The entire heating element substrate 2 is arranged on the common wiring 321. In other words, the outer edge 2W of the heating element substrate 2 is positioned inward of the outer edge 32W of the second wiring layer 32. Thus, the main surface of the heating element substrate 2 can be made parallel to the second main surface 31A of the ceramic substrate 31. This suppresses the inclination of the heating element substrate 2, thereby making it possible to suppress printing irregularity.

FIG. 4A is a cross-sectional view of the thermal print head 1 according to the first embodiment taken along IVA-IVA in FIG. 2B. The wire 8c is electrically connected between the heating element substrate 2 and the wiring substrate 3. More specifically, as illustrated in FIG. 4B, the first end portion 8ca of the wire 8c is connected to the protrusion 321a of the common wiring 321. The second end portion 8cb of the wire 8c (see FIG. 4C) is connected to the connecting portion 413 of the common electrode 41 illustrated in FIG. 6.

As illustrated in FIG. 4B, the first protective film 342 is arranged on the upper surface of the common wiring 321. However, the first protective film 342 is not arranged on the protrusion 321a. The protrusion 321a is exposed from the opening 21 where the first protective film 342 is not formed. Therefore, the first end portion 8ca of the wire 8c can be bonded to the protrusion 321a.

The lower surface of the heating element substrate 2 is bonded onto the first protective film 342 by the adhesive 13. The third protective film 11 is arranged on the upper surface of the common wiring 321 between the protrusion 321a of the second wiring layer 32 and the heating element substrate 2. The third protective film 11 suppresses the adhesive 13 flowing into the opening 21, thereby ensuring a stable electrical connection between the protrusion 321a and the wire 8c.

As illustrated in FIG. 4A, by increasing the distance W between the platen roller 10 and the second protective film 6, sufficient pressing force of the platen roller 10 with respect to the convex portion 2a (heating portion) can be ensured, thereby improving printing accuracy. In order to increase the distance W, the height (length in the Z direction) of the second protective film 6 may be reduced. Thus, the height of the second protective film 6 is reduced by reducing the height in the Z direction from the second end portion 8cb of the wire 8c to the top of the wire 8c by the following method.

The method of manufacturing the thermal print head 1 includes a first step of electrically connecting the first wiring layer 40 of the heating element substrate 2 and the second wiring layer 32 of the wiring substrate 3 using the wire 8c, and a second step of sealing the wire 8c with the second protective film 6. In the first step, after the first end portion 8ca of the wire 8c is bonded to the second wiring layer 32 of the wiring substrate 3, the second end portion 8cb of the wire 8c is bonded to the first wiring layer 40 of the heating element substrate 2. Ball bonding and wedge bonding can be used regardless of the bonding method. In the case of ball bonding, in the first bond, a ball formed by melting the wire tip is crimped onto the second wiring layer 32 and bonded thereon by ultrasonic vibration. A wire loop is formed by pulling the wire toward the upper surface of the heating element substrate 2 at an appropriate height and angle. Thereafter, in the second bond, the wire is then brought into contact with the first wiring layer 40 of the heating element substrate 2 and crimped onto the first wiring layer 40 by applying ultrasonic waves and pressure. The wire is then cut. The bonding is performed in the order of the second wiring layer 32 of the wiring substrate 3 and the first wiring layer 40 of the heating element substrate 2. Thus, the height in the Z direction from the second end portion 8cb of the wire 8c to the top portion of the wire 8c can be reduced, thereby also making it possible to reduce the height (length in the Z direction) of the second protective film 6. In the case of ball bonding, as illustrated in FIG. 4B, a ball is formed at the first end portion 8ca of the wire 8c on the second wiring layer 32.

Examples of the dimensions of the respective components of the thermal print head 1 are as follows: The length 2W of the heating element substrate 2 in the Y direction is 2.9 mm, and the length of the heating element substrate 2 in the Z direction is 0.7 mm. The length 32W of the common wiring 321 (see FIG. 3C) in the Y direction overlapping with the heating element substrate 2 is 3.2 mm. The length of the wiring substrate 3 in the X direction is 117 mm, the length of the wiring substrate 3 in the Y direction is 10.0 mm, and the length of the wiring substrate 3 in the Z direction is 1.0 mm. The length from the upper surface of the heating element substrate 2 to the top surface of the second protective film 6 in the Z direction is 0.4 mm. The length of the third protective film 11 in the Y direction is 100 μm, and the length of the third protective film 11 in the Z direction is 15 μm. The length of the adhesive 13 in the Z direction is 20 μm. The length of the first protective film 342 in the Z direction is 4 μm. The length of the second wiring layer 32 in the Z direction is 30 μm.

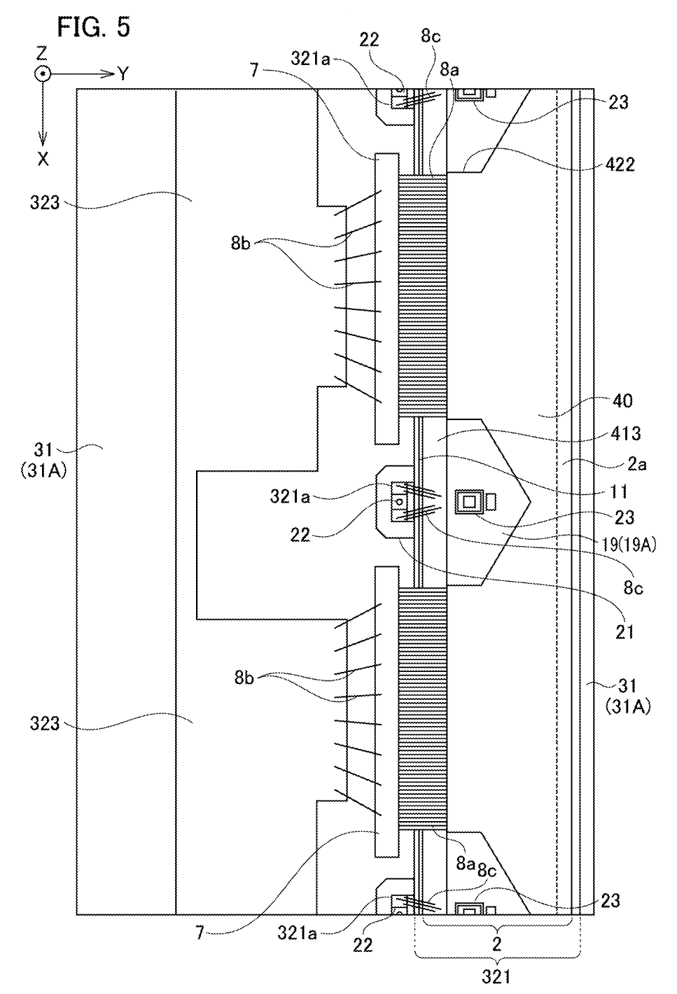

FIG. 5 is an enlarged plan view of the region G5 in FIG. 2B. The second wiring layer 32 is screen printed on the upper surface (second main surface 31A) of the ceramic substrate 31. FIG. 5 illustrates the common wiring 321 and the ground wiring 323 included in the second wiring layer 32, but omits the individual wiring 322 arranged between the common wiring 321 and the ground wiring 323. The common wiring 321 and the ground wiring 323 extend in the main scanning direction (X direction). On the upper surface of the ceramic substrate 31 between the common wiring 321 and the ground wiring 323, a plurality of drive ICs 7 are arranged at predetermined intervals in the X direction.

The heating element substrate 2 is arranged on the common wiring 321. As seen from the normal direction (Z direction) of the second main surface 31A, the entire heating element substrate 2 overlaps with the common wiring 321 included in the second wiring layer 32.

The heating element substrate 2 extends in the X direction in the same manner as the common wiring 321. On the first main surface 19A of the semiconductor substrate 19 provided in the heating element substrate 2, the connecting portion 413 that connects the first wiring layer 40 and the common electrode 41 is arranged. Note that FIG. 5 illustrates an outer shape of the first wiring layer 40. The plurality of common electrodes 41 and the plurality of individual electrodes 42 constituting the first wiring layer 40 are illustrated in FIG. 6. The drive IC 7 and the individual pad 422 (see FIG. 6) of the plurality of individual electrodes 42 are electrically connected by the plurality of wires 8a.

The protrusion 321a of the common wiring 321 is exposed from the opening 21 (see FIG. 4B) where the first protective film 342 is not formed. The connecting portion 413 of the common electrode 41 is electrically connected to the protrusion 321a of the common wiring 321 by the plurality of wires 8c. The ground wiring 323 and the drive IC 7 are electrically connected by the plurality of wires 8b. Note that in FIG. 5, a plurality of wires electrically connecting the individual wiring 322 and the drive IC 7 are not illustrated. Further, a thermistor for detecting a temperature and a bypass capacitor for allowing an AC component such as noise superimposed on the DC power supplied to the drive IC 7 to flow to the ground may be mounted on the upper surface (second main surface 31A) of the ceramic substrate 31.

Power signals on the high potential side and the low potential side input from the connector 5 are supplied to the heating element substrate 2 via the common wiring 321 and the ground wiring 323 on the ceramic substrate 31. A drive signal for individually driving the plurality of heating portions 24 is input from the connector 5 to the drive IC 7 via the individual wiring 322. The drive IC 7 can cause the plurality of heating portions 24 to generate heat individually by individually energizing the plurality of individual electrodes 42.

The third protective film 11 is arranged between the protrusion 321a and the heating element substrate 2. The third protective film 11 suppresses the adhesive that is used for bonding the heating element substrate 2 to the top surface of the wiring substrate 3 flowing into the opening 21, thereby ensuring a stable electrical connection between the wire 8c and the protrusion 321a.

A first alignment mark 22 having a predetermined positional relationship with the heating element substrate 2 is formed on the second main surface 31A of the ceramic substrate 31. The first alignment mark 22 belongs to the same layer as the second wiring layer 32 and is formed simultaneously with the second wiring layer 32 by screen printing. For example, the first alignment mark 22 may be a part of the protrusion 321a of the common wiring 321. The first alignment mark 22 exposed through the opening 21 is directly visible, thereby making an accurate alignment possible.

In the method of manufacturing the thermal print head 1, an alignment of the heating element substrate 2 can be performed with respect to the second main surface 31A of the ceramic substrate 31 based on the first alignment mark 22. In addition, an alignment of the wiring substrate 3 and the heating element substrate 2 can be performed such that the heating element substrate 2 has a predetermined positional relationship with respect to the first alignment mark 22.

A second alignment mark 23 having a predetermined positional relationship with the first alignment mark 22 is formed on the first main surface 19A of the semiconductor substrate 19. The second alignment mark 23 is formed in a region of the first main surface 19A of the semiconductor substrate 19 where the first wiring layer 40 is not formed. The second alignment mark 23 belongs to the same layer as the first wiring layer 40 and is formed simultaneously with the first wiring layer 40.

In the method of manufacturing the thermal print head 1, an alignment of the heating element substrate 2 can be performed with respect to the second main surface 31A of the ceramic substrate 31 such that the second alignment mark 23 is at a predetermined position with respect to the first alignment mark 22.

Although the present disclosure has been described in detail, it will be apparent to those skilled in the art that the present disclosure is not limited to the embodiment(s) described herein. One or more elements of one embodiment can be combined with one or more elements of another embodiment. The present disclosure can be implemented in modified and changed forms without departing from the spirit and scope of the present disclosure as defined by the appended claims. Accordingly, the description of the present disclosure is for illustrative purposes and is not intended to be restrictive in any way.

### Supplementary notes

The technical ideas that can be understood from the present disclosure are described below. It should be noted that the components described in the notes are designated by reference numerals of the corresponding components in the embodiments for the purpose of assisting understanding and not for the purpose of limitation. The reference numerals are illustrated by way of example to aid understanding, and the components described in the respective notes should not be limited to those indicated by reference numerals.

### Supplementary note 1

The thermal print head 1 is provided with the heating element substrate 2 and the wiring substrate 3. The heating element substrate 2 includes: the semiconductor substrate 19 having the first main surface 19A; a plurality of heating portions 24 arranged on the first main surface 19A in the main scanning direction (X direction); and the first wiring layer 40 arranged on the first main surface 19A and constituting an energizing path to the plurality of heating portions 24. The wiring substrate 3 includes: the ceramic substrate 31 having the second main surface 31A; and the second wiring layer 32 arranged on the second main surface 31A. The second wiring layer 32 is electrically connected to the first wiring layer 40. The third main surface of the semiconductor substrate 19 facing opposite to the first main surface 19A is bonded to the upper surface 3A of the wiring substrate 3 where the second wiring layer 32 is formed. As seen from the normal direction (Z direction) of the second main surface 31A, the entire heating element substrate 2 overlaps with the second wiring layer 32. Thus, the main surface of the heating element substrate 2 can be made parallel to the second main surface 31A of the ceramic substrate 31. This suppresses the inclination of the heating element substrate 2, thereby making it possible to suppress printing irregularity.

### Supplementary note 2

In the thermal print head 1 according to Supplementary note 1, the wiring substrate 3 may further have the glaze layer 341 and the first protective film 342 arranged on the second main surface 31A, and the glaze layer 341, the second wiring layer 32, and the first protective film 342 may be laminated in this order on the second main surface 31A. The wiring substrate 3 can be manufactured by a thick film structure with high productivity.

### Supplementary note 3

In the thermal print head 1 according to Supplementary note 1 or 2, the first alignment mark 22 having a predetermined positional relationship with the heating element substrate 2 may be formed on the second main surface 31A of the ceramic substrate 31. By using the first alignment mark 22, an alignment of the heating element substrate 2 can be performed accurately with respect to the wiring substrate 3.

### Supplementary note 4

In the thermal print head 1 according to Supplementary note 2, the second alignment mark 23 having a predetermined positional relationship with the first alignment mark 22 may be formed on the first main surface 19A of the semiconductor substrate 19. By combining the first alignment mark 22 and the second alignment mark 23, an alignment of the heating element substrate 2 can be more accurately performed with respect to the wiring substrate 3.

### Supplementary note 5

The thermal print head 1 according to any one of Supplementary notes 1 to 4 may further include the drive IC 7 that is arranged on the second main surface 31A of the ceramic substrate 31 and electrically connected to the first wiring layer 40 and the second wiring layer 32, and the second protective film 6 that seals the drive IC 7.

### Supplementary note 6

The thermal print head 1 according to any one of Supplementary notes 1 to 5 may further include the wire 8c that electrically connects the first wiring layer 40 and the second wiring layer 32, and the third protective film 11 that is arranged on the second main surface 31A between the protrusion 321a of the second wiring layer 32 to which the wire 8c is bonded and the heating element substrate 2. The third protective film 11 suppresses the adhesive that is used for bonding the heating element substrate 2 to the wiring substrate 3 flowing into the protrusion 321a, thereby ensuring a stable electrical connection between the protrusion 321a and the wire 8c.

### Supplementary note 7

In the thermal print head 1 according to any one of Supplementary notes 1 to 6, of the main surfaces of the ceramic substrate 31, the second wiring layer 32 may be printed only on the second main surface 31A. The manufacturing cost can be reduced as compared with printing on a plurality of surfaces.

### Supplementary note 8

In the thermal print head 1 according to Supplementary note 7, the printing may be screen printing. The wiring substrate 3 can be manufactured inexpensively as compared with a PCB.

### Supplementary note 9

In the thermal print head 1 according to Supplementary note 7 or 8, the surface of the second wiring layer 32 may be covered with the first protective film 342 made of an insulating film. The printed surface of the wiring substrate 3 can be protected by the first protective film 342.

### Supplementary note 10

The thermal print head 1 according to any one of Supplementary notes 1 to 9 may further include the heat sink 4 that is thermally connected to the fourth main surface 31B of the ceramic substrate 31 facing in the opposite direction to the second main surface 31A. The heat generated in the heating element substrate 2 can be discharged from the heat sink 4 via the wiring substrate 3.

### Supplementary note 11

The thermal print head 1 according to any one of Supplementary notes 1 to 10 may further include the connector 5 that is fixed to the wiring substrate 3 and electrically connected to the second wiring layer 32, and provided for electrical connection with external devices.

### Supplementary note 12

The method of manufacturing the thermal print head 1 according to any one of Supplementary notes 1 to 11 includes: a step of electrically connecting a first wiring layer 40 and a second wiring layer 32 using the wire 8c; and a step of sealing the wire 8c with the second protective film 6. In the step of electrically connecting a first wiring layer 40 and a second wiring layer 32 using the wire 8c, after the first end portion 8ca of the wire 8c is bonded to the second wiring layer 32, the second end portion 8cb of the wire 8c is bonded to the first wiring layer 40. The height in the Z direction from the second end portion 8cb of the wire 8c to the top portion of the wire 8c can be reduced, thereby also making it possible to reduce the height (length in the Z direction) of the second protective film 6. By increasing the distance W between the platen roller 10 and the second protective film 6, sufficient pressing force of the platen roller 10 with respect to the convex portion 2a (heating portion) can be ensured, thereby improving printing accuracy.

### Supplementary note 13

In the method of manufacturing the thermal print head 1 according to Supplementary note 3, an alignment of the heating element substrate 2 may be performed with respect to the second main surface 31A of the ceramic substrate 31 based on the first alignment mark 22. Using the first alignment mark 22, an alignment of the heating element substrate 2 can be accurately performed with respect to the wiring substrate 3.

### Supplementary note 14

In the method of manufacturing the thermal print head 1 according to Supplementary note 4, an alignment of the heating element substrate 2 may be performed with respect to the second main surface 31A of the ceramic substrate 31 such that the second alignment mark 23 is at a predetermined position with respect to the first alignment mark 22. By combining the first alignment mark 22 and the second alignment mark 23, an alignment of the heating element substrate 2 can be more accurately performed with respect to the wiring substrate 3.

1. A thermal print head comprising:
a heating element substrate that includes a semiconductor substrate having a first main surface, a plurality of heating portions arranged on the first main surface in a main scanning direction, and a first wiring layer arranged on the first main surface and constituting an energizing path to the plurality of heating portions; and
a wiring substrate that includes a ceramic substrate having a second main surface, and a second wiring layer arranged on the second main surface, wherein
the second wiring layer is electrically connected to the first wiring layer,
a third main surface of the semiconductor substrate facing opposite to the first main surface is bonded to an upper surface of the wiring substrate where the second wiring layer is formed, and
the entire heating element substrate overlaps with the second wiring layer as seen from a normal direction of the second main surface.

2. The thermal print head according to claim 1, wherein
the wiring substrate further includes a glaze layer and a first protective film arranged on the second main surface, and
the glaze layer, the second wiring layer, and the first protective film are laminated in this order on the second main surface.

3. The thermal print head according to claim 1, wherein
a first alignment mark having a predetermined positional relationship with the heating element substrate is formed on the second main surface of the ceramic substrate.

4. The thermal print head according to claim 3, wherein
a second alignment mark having a predetermined positional relationship with the first alignment mark is formed on the first main surface of the semiconductor substrate.

5. The thermal print head according to claim 1, further comprising:
a drive IC that is arranged on the second main surface and electrically connected to the first wiring layer and the second wiring layer; and
a second protective film that seals the drive IC.

6. The thermal print head according to claim 1, further comprising:
a wire that electrically connects the first wiring layer and the second wiring layer; and
a third protective film that is arranged on the second main surface between a protrusion of the second wiring layer to which the wire is bonded and the heating element substrate.

7. The thermal print head according to claim 1, wherein
of main surfaces of the ceramic substrate, the second wiring layer is printed only on the second main surface.

8. The thermal print head according to claim 7, wherein
the printing is screen printing.

9. The thermal print head according to claim 7, wherein
a surface of the second wiring layer is covered with the first protective film made of an insulating film.

10. The thermal print head according to claim 1, further comprising:
a heat sink that is thermally connected to a fourth main surface of the ceramic substrate facing in an opposite direction to the second main surface.

11. The thermal print head according to claim 1, further comprising:
a connector that is fixed to the wiring substrate and electrically connected to the second wiring layer, and provided for electrical connection with external devices.

12. A method of manufacturing the thermal print head according to claim 1, comprising:
a step of electrically connecting the first wiring layer and the second wiring layer using a wire; and
a step of sealing the wire with a second protective film, wherein
in the step of electrically connecting the first wiring layer and the second wiring layer using a wire, after a first end portion of the wire is bonded to the second wiring layer, a second end portion of the wire is bonded to the first wiring layer.

13. The method of manufacturing the thermal print head according to claim 3, comprising:
a step of performing an alignment of the heating element substrate with respect to the second main surface of the ceramic substrate based on the first alignment mark.

14. The method of manufacturing the thermal print head according to claim 4, comprising:
a step of performing an alignment of the heating element substrate with respect to the second main surface of the ceramic substrate such that the second alignment mark is at a predetermined position with respect to the first alignment mark.
